(19) United States
(12) Patent Application Publication
(10) Pub. No.: US 2026/0165087 A1
(43) Pub. Date: Jun. 11, 2026

(54) APPARATUS AND METHOD FOR PROCESSING SUBSTRATE

(71) Applicant: SAMSUNG ELECTRONICS CO., LTD., Suwon-si (KR)

(72) Inventors: Sunjeong KIM, Suwon-si (KR); Kein KIM, Suwon-si (KR); lk Soo KIM, Suwon-si (KR); Jaebeom PARK, Suwon-si (KR); Taehwan CHA, Suwon-si (KR)

(73) Assignee: SAMSUNG ELECTRONICS CO., LTD., Suwon-si (KR)

(21) Appl. No.: 19/179,553

(22) Filed: Apr. 15, 2025

(30) Foreign Application Priority Data
Oct. 14, 2024 (KR) 10-2024-0139845

(51) Int. Cl. H10P 72/76; C23C 16/455; C23C 16/458; C23C 16/50; H01J 37/32; H10P 72/72

(52) U.S. Cl. CPC H10P 72/7608; C23C 16/45565; C23C 16/4586; C23C 16/50; H01J 37/3244; H01J 37/32724; H10P 72/72; H01J 2237/2007

(57) ABSTRACT

Provided is an apparatus for processing a substrate and a method associated therewith. The apparatus includes: a chamber including an inner space; an electrostatic chuck in a lower portion of the inner space, wherein the electrostatic chuck is configured to support and adhere to the substrate; a shower head in an upper portion of the inner space, the shower head including a gas flow path configured to supply a processing gas into the inner space; and a planarization member configured to apply pressure to at least one region of the substrate in a direction toward the electrostatic chuck, wherein the electrostatic chuck includes a heater capable of heating the substrate.

### CROSS-REFERENCE TO RELATED APPLICATION

This application claims priority to Korean Patent Application No. 10-2024-0139845, filed in the Korean Intellectual Property Office on Oct. 14, 2024, the entire contents of which are hereby incorporated by reference.

### BACKGROUND

### 1. Field

The present disclosure relates to an apparatus for, and a method of, processing a substrate.

### 2. Description of Related Art

Semiconductor devices are formed through various semiconductor manufacturing processes such as deposition, ion implantation, photolithography, or etching. Deposition is a process of forming a thin film or material film on a substrate, and methods such as chemical vapor deposition (CVD), atomic layer deposition (ALD), etc. are used for the deposition process.

An electrostatic chuck may be used to fix the substrate during processing of the semiconductor device, such as during a deposition process. Further, if the substrate is heated to a high temperature during processing, such as during a deposition process, the substrate may thermally expand or bend at the edges due to the heat. If chucking with the electrostatic chuck is performed with the edge of the substrate in the bent state, defects such as cracks may occur on a backside of the substrate, which is problematic.

### SUMMARY

Provided is an apparatus and a method for processing a substrate to reduce defects caused by bending of an edge of the substrate during substrate processing.

According to one or more embodiments of the present disclosure, an apparatus for processing a substrate may planarize a portion of the substrate bent by heat treatment, etc., thereby facilitating substrate adhesion by the electrostatic chuck.

The apparatus for processing the substrate may minimize interferences that may occur due to the presence of the planarization member while performing the planarization process on the bent substrate and the subsequent processes.

According to one or more embodiments of the present disclosure, the method for processing the substrate may include planarization of a portion of the substrate bent by heat treatment, etc., thereby effectively executing the substrate adhesion by the electrostatic chuck and subsequent processes.

According to an aspect of the disclosure, an apparatus for processing a substrate includes: a chamber including an inner space; an electrostatic chuck in a lower portion of the inner space, wherein the electrostatic chuck is configured to support and adhere to the substrate; a shower head in an upper portion of the inner space, the shower head including a gas flow path configured to supply a processing gas into the inner space; and a planarization member configured to apply pressure to at least one region of the substrate in a direction toward the electrostatic chuck, wherein the electrostatic chuck includes a heater capable of heating the substrate.

According to an aspect of the disclosure, an apparatus for processing a substrate includes: a chamber defining an inner space; an electrostatic chuck in a lower portion of the inner space, wherein the electrostatic chuck is configured to support and adhere to the substrate; a gas supply configured to supply a processing gas to the inner space; a shower head in an upper portion of the inner space, the shower head including a gas flow path connected to the gas supply; a power supply configured to supply power to generate a plasma in the inner space; and a planarization member configured to apply pressure to at least one region of the substrate in a direction toward the electrostatic chuck, wherein the electrostatic chuck includes a heater capable of heating the substrate.

According to an aspect of the disclosure, a method for processing a substrate includes: supporting the substrate using an electrostatic chuck in a chamber; heating the substrate by the electrostatic chuck; planarizing the substrate by applying pressure to at least one region of the substrate using a planarization member inside the chamber; securing the substrate by applying an electric force using the electrostatic chuck; separating the planarization member from the substrate; and supplying a processing gas into the chamber through a shower head inside the chamber, wherein the planarization member is on at least one of an inner surface of a sidewall of the chamber or a lower surface of the shower head.

### BRIEF DESCRIPTION OF THE DRAWINGS

The above and other aspects and features of certain embodiments of the present disclosure will become more apparent from the following description taken in conjunction with the accompanying drawings, in which:

FIG. 1A is a cross-sectional view illustrating a substrate thermally expanded by high temperature;

FIG. 1B is a diagram illustrating an example of falling particles formed due to a thermally expanded substrate;

FIG. 1C is a diagram illustrating an example of plate-shaped particles formed due to a thermally expanded substrate;

FIG. 2A is a schematic diagram illustrating a substrate processing apparatus according to one or more embodiments of the present disclosure;

FIG. 2B is a schematic diagram illustrating a portion of the substrate processing apparatus according to one or more embodiments of the present disclosure;

FIG. 2C is a schematic cross-sectional view illustrating a portion of the substrate processing apparatus according to one or more embodiments of the present disclosure;

FIG. 2D is a schematic diagram illustrating a sidewall of a chamber in which a planarization member and a driving unit of the substrate processing apparatus are disposed according to one or more embodiments of the present disclosure;

FIG. 3A is a schematic diagram illustrating a portion of a substrate processing apparatus according to one or more embodiments of the present disclosure;

FIG. 3B is a schematic cross-sectional view illustrating a portion of the substrate processing apparatus according to one or more embodiments of the present disclosure;

FIG. 3C is a schematic diagram illustrating a portion of the substrate processing apparatus according to one or more embodiments of the present disclosure;

FIG. 4A is a diagram illustrating a portion of a chamber in which a planarization member and a receiving groove of the substrate processing apparatus are disposed according to one or more embodiments of the present disclosure;

FIG. 4B is a diagram illustrating a portion of a chamber in which the planarization member and the receiving groove of the substrate processing apparatus are disposed according to one or more embodiments of the present disclosure;

FIG. 4C is a diagram illustrating a structure of the planarization member and the receiving groove of the substrate processing apparatus according to one or more embodiments of the present disclosure;

FIG. 5A is a schematic diagram illustrating a portion of a substrate processing apparatus;

FIG. 5B is a schematic cross-sectional view illustrating a portion of the substrate processing apparatus according to one or more embodiments of the present disclosure;

FIG. 6A is a perspective view illustrating a lower surface of a shower head of the substrate processing apparatus according to one or more embodiments of the present disclosure;

FIG. 6B is a plan view of the shower head of the substrate processing apparatus of FIG. 6A;

FIG. 7A is a perspective view illustrating a lower surface of the shower head of the substrate processing apparatus according to one or more embodiments of the present disclosure;

FIG. 7B is a plan view of the shower head of the substrate processing apparatus of FIG. 7A;

FIG. 8 is a flowchart provided to explain a method for processing a substrate according to one or more embodiments of the present disclosure; and

FIG. 9 is a schematic diagram illustrating a substrate processing apparatus according to one or more embodiments of the present disclosure.

### DETAILED DESCRIPTION

Hereinbelow, a semiconductor package according to one or more embodiments of the present disclosure will be described in detail with reference to the drawings.

In the following description, like reference numerals refer to like elements throughout the specification. Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection includes “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The various actions, acts, blocks, steps, or the like in the flow diagrams may be performed in the order presented, in a different order, or simultaneously. Further, in one or more embodiments, some of the actions, acts, blocks, steps, or the like may be omitted, added, modified, skipped, or the like without departing from the scope of the disclosure.

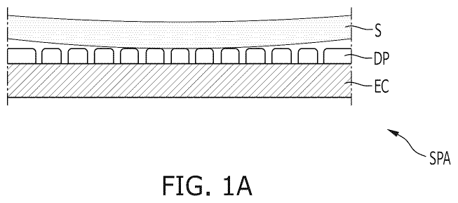

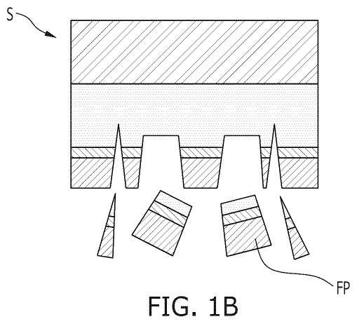

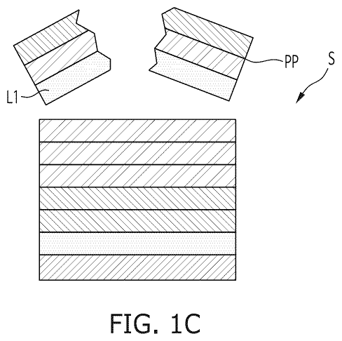

FIG. 1A is a cross-sectional view illustrating a substrate thermally expanded due to high temperature. FIG. 1B is a diagram illustrating an example of falling particles formed due to the thermally expanded substrate. FIG. 1C is a diagram illustrating an example of plate-shaped particles formed due to the thermally expanded substrate.

Referring to FIG. 1A, a substrate may be disposed on an electrostatic chuck EC of an example substrate processing apparatus SPA. The example substrate processing apparatus SPA may fix the substrate S on the electrostatic chuck EC. For example, the electrostatic chuck EC may form an electric field inside the substrate processing apparatus SPA to apply an electric force to the substrate. In this case, the electric force may be an electrostatic force. The substrate S may be adhered to and fixed on the electrostatic chuck EC of the substrate processing apparatus SPA by the electric force.

The substrate processing apparatus SPA may perform a pre-processing process of heating the substrate S at high temperature before performing the deposition process on the substrate S. The substrate S may be bent due to the high-temperature heating process. For example, an edge of the substrate S may be bent in a direction away from the electrostatic chuck EC of the substrate processing apparatus SPA. Referring to the cross-sectional view of FIG. 1A, a central portion of the substrate S may be maintained in contact with the electrostatic chuck EC, while the edge of the substrate S may be bent away from the electrostatic chuck EC in an approximately bow-like shape. For example, as the distance from the center of the substrate S increases, the substrate may be bent further away from the electrostatic chuck. The substrate S that is bent due to heat in the process of being adhered to and fixed on the electrostatic chuck EC by the substrate processing apparatus SPA may be impacted by a protrusion DP formed on an upper surface of the electrostatic chuck EC, and this may result in a defect on a back surface of the substrate S. For example, the edge of the substrate S bent to a larger angle may receive a greater impact than an inner portion of the substrate S which is less bent. In this case, scratches and cracks may occur on the back surface of the substrate S in contact with the electrostatic chuck EC due to the impact applied to the substrate S during substrate processing. Further, damage may occur to the films deposited on the substrate S, which is positioned close to the backside of the substrate S.

Referring to FIG. 1B, if the warpage of the substrate S occurs as described above, falling particles FP may occur on the back surface of the substrate S. If the falling particles FP are detached from the substrate, irregularities may be formed on the back surface of the substrate S, resulting in defects. In addition, if a plurality of substrates S are stacked, the falling particles FP detached from one substrate S may be accumulated on another substrate S, resulting in defects.

Referring to FIG. 1C, when the warpage of the substrate S occurs as described above, one of the films disposed close to the back surface of the substrate S may suffer problems such as damage or melting. For example, a first film L1 disposed on the back surface of the substrate S may be detached from the substrate S, and plate-shaped particles PP may be generated from the first film L1 and the films adjacent to the first film L1 detached from the substrate S. The plate-shaped particles PP may be detached from the substrate, and if a plurality of substrates S are stacked, the plate-shaped particles PP detached from one substrate S may accumulate on another substrate S, resulting in defects.

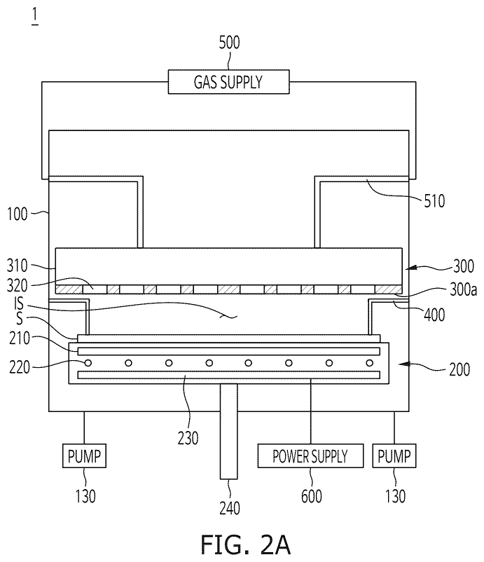

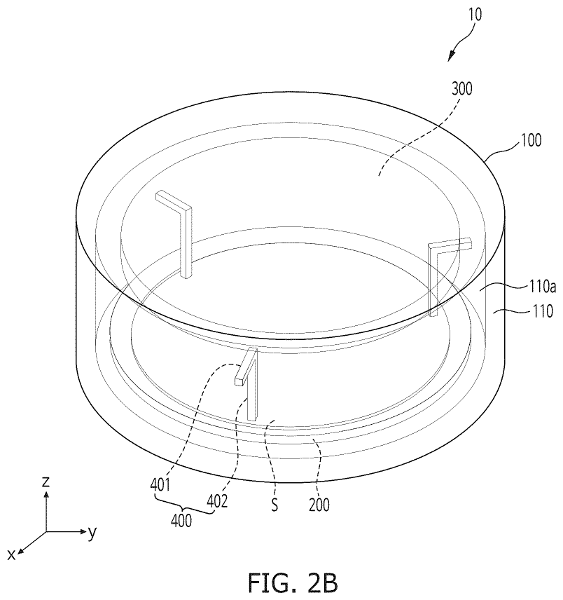

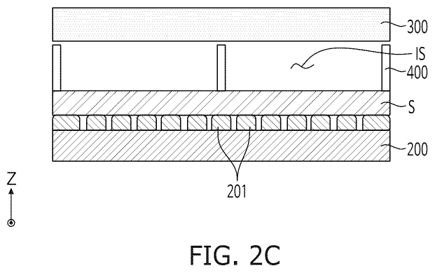

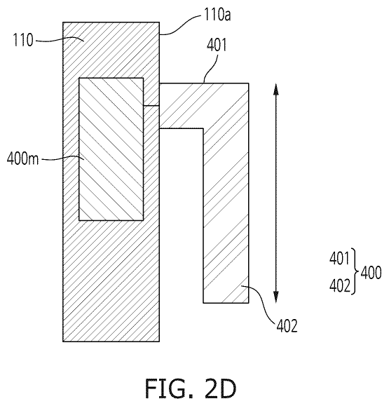

FIG. 2A is a schematic diagram illustrating a substrate processing apparatus according to one or more embodiments. FIG. 2B is a schematic diagram illustrating a portion of the substrate processing apparatus according to one or more embodiments. FIG. 2C is a schematic cross-sectional view illustrating a portion of the substrate processing apparatus according to one or more embodiments. FIG. 2D is a schematic diagram illustrating a sidewall of a chamber in which a planarization member and a driving unit of the substrate processing apparatus are disposed according to one or more embodiments.

Referring to FIGS. 2A to 2C, a substrate processing apparatus 1 may include a chamber 100, an electrostatic chuck 200, a shower head 300, a planarization member 400, a gas supply 500, a power supply 600, etc.

The substrate processing apparatus 10 may include the chamber 100 including an inner space IS for processing the substrate S. The electrostatic chuck 200 may be disposed in a lower portion of the inner space IS, configured to support the substrate S, and adhere to the substrate S by applying the electric force. The shower head 300 may be disposed in an upper portion of the inner space IS and include a gas flow path 310 for supplying gas to the substrate S and planarization member 400 configured to apply pressure to at least one region of the substrate S in a direction toward the electrostatic chuck 200. The electrostatic chuck 200 may include a heater 210 that may heat the substrate. Further, the shower head 300 may include a plurality of gas injectors 320 to uniformly supply a gas supplied through the gas flow path 310 onto the substrate S.

The planarization member 400 may be disposed in the inner space IS of the chamber 100. The planarization member 400 may be disposed on a sidewall 110 of the chamber 100. The planarization member 400 may be disposed on an inner surface 110a of the sidewall 110 that faces the inner space IS. The substrate processing apparatus 10 may be configured to apply pressure to at least one region of the substrate S through the planarization member 400. For example, if the substrate S includes a portion bent by heat, the planarization member 400 may apply force on the bent portion to cause the bent portion of the substrate S to be bent in the opposite direction so that the entire substrate S is processed in an approximately flat state. Accordingly, with the entire substrate S being maintained in the approximately flat shape, the electrostatic chuck 200 may generate an electric force to adhere to the substrate S, which in turn facilitates the subsequent processes that may follow. Therefore, in the subsequent processes applied to the substrate S, problems that may occur due to bending of the substrate S may be reduced or prevented. For example, the falling particles and plate-shaped particles, which are generated as a portion of the bent substrate S is impacted by the surface of the electrostatic chuck 200, may be prevented or at least mitigated.

The substrate processing apparatus 10 may include the chamber 100 including the inner space IS for processing the substrate S. The inner space IS may be sealed from the outside by the chamber 100. The chamber 100 may include the sidewall 110. For example, a thickness direction of the substrate S disposed inside the substrate processing apparatus 10 may be parallel to a height direction of the sidewall 110. For example, the sidewall 110 may have a cylindrical shape, but the disclosure is not limited thereto.

A process of heating the substrate S in the inner space IS of the chamber 100, a process of chucking, and/or a process of depositing a film on the substrate S may be sequentially performed. For example, the inner space IS of the chamber 100 may provide a space where plasma is formed and/or the substrate is processed. One side of the chamber 100 may be provided with a path through which the substrate S is loaded and unloaded. The chamber 100 may include a metallic material, for example, aluminum (Al) or an alloy including the same. The interior of the chamber 100 may be formed of an insulating material to prevent damage from plasma or generation of particles. For example, the interior of the chamber 100 may include quartz, Al₂O₃, AlN, Y₂O₃, etc.

An exhaust port may be formed at one side of the chamber 100, and the exhaust port may be connected to a pump 130. For example, the exhaust port and the pump 130 of the chamber 100 may be disposed in a lower portion of the chamber 100. The pump 130 may be connected to the exhaust port to discharge the gas inside the chamber 100 to the outside. The pump 130 may be configured to adjust the pressure within the chamber 100 to depressurize the atmosphere in the chamber 100 to a predetermined degree of vacuum. The pump 130 may discharge the gas inside the chamber 100 to the outside to maintain a vacuum state within the chamber 100. For example, the pump 130 may be a vacuum pump. For example, a control unit may control the pump 130 to adjust the pressure state inside the chamber 100.

The chamber 100 may be configured to move in a direction parallel to the thickness direction of the substrate S. For example, the chamber 100 may include a driving unit (e.g., a linear motor), and the driving unit may move the chamber 100 up and down. When the chamber 100 is moved in the thickness direction of the substrate S by the driving unit, the position of the substrate S in the chamber 100 may be fixed. For example, the electrostatic chuck 200 may be fixedly disposed by a support shaft or a drive shaft 240 so that the position of the substrate S supported by the electrostatic chuck 200 may be fixed and not changed. As the chamber 100 is moved in a direction parallel to the thickness direction of the substrate S, the planarization member 400 fixedly disposed on the sidewall 110 of the chamber 100 may also be moved in a direction parallel to the thickness direction of the substrate S to contact a partial region of the substrate S. The configuration and operation of the chamber 100 and the planarization member 400 will be described below.

The substrate processing apparatus 10 may include the electrostatic chuck 200. The electrostatic chuck 200 may be disposed in a lower portion of the inner space IS of the chamber 100. Further, the electrostatic chuck 200 may be configured to support the substrate S. Further, the electrostatic chuck 200 may be configured to apply the electric force to the substrate S. For example, the electrostatic chuck 200 may support the substrate S through an upper surface thereof, which is configured such that the substrate S is disposed at a predetermined position thereof. For example, protrusions (or dimples) 201 may be disposed on the upper surface of the electrostatic chuck 200, and the substrate S may be supported by protrusions 201 of the electrostatic chuck 200. The substrate S may be substantially disposed on the protrusions 201.

The electrostatic chuck 200 may include the heater 210, and heat may be applied to the substrate S by the heater 210. For example, the heater 210 may be disposed inside the electrostatic chuck 200. The heater 210 may include a heating wire, and the heating wire may be disposed in various shapes as needed. For example, the heating wire of the heater 210 may be in a spiral shape that starts near the center of the plane of the electrostatic chuck 200, or may have a zigzag shape starting from one end of the plane of the electrostatic chuck 200. However, the disclosure is not limited to the above, and the heating wire may have a shape of a plurality of lines, or may have a shape of a plurality of circles or polygons centered around the center of the plane of the electrostatic chuck 200.

The temperature inside the substrate processing apparatus 10 may increase due to heat generated by the heater 210 of the electrostatic chuck 200. For example, the temperature inside the substrate processing apparatus 10 may be about 550 degrees Celsius to about 700 degrees Celsius. However, the disclosure is not limited to the above, and the temperature inside the substrate processing apparatus 10 may be adjusted to another temperature range by the heater 210 as need arises. As the temperature inside the substrate processing apparatus 10 rises, a portion (e.g., an edge portion) of the substrate S disposed inside the substrate processing apparatus 10 may be bent due to thermal expansion. Accordingly, the bent region of the substrate S may be spaced apart from the protrusions 201 of the electrostatic chuck 200.

The electrostatic chuck 200 may apply an electric force to the substrate S. In this case, the electric force may be an electrostatic force. For example, the electrostatic chuck 200 may include a chucking electrode 220 therein, and voltage may be applied to the chucking electrode 220 by an external power source. For example, the chucking electrode 220 may be disposed in a lower portion of the heater 210, but the disclosure is not limited thereto.

When voltage is applied to the chucking electrode 220 of the electrostatic chuck 200, the electrostatic chuck 200 may apply the electric force to a peripheral region including the substrate S, and accordingly, the substrate S may adhere to the electrostatic chuck 200 and be fixed on the electrostatic chuck 200. For example, the electric force may act on the substrate S in a direction that brings the substrate S closer to the electrostatic chuck 200, causing the substrate S to be pulled towards and fixed onto the upper surface of the electrostatic chuck 200. In this case, a portion of the substrate S, which is bent by thermal expansion, may be moved in a direction closer to the electrostatic chuck 200 by the electric force or may be unfolded in a direction closer to the electrostatic chuck 200. As the bent region of the substrate S is moved or deformed, the bent region of the substrate S may collide onto the electrostatic chuck 200 or the protrusions 201 disposed on the electrostatic chuck 200. Accordingly, damage may occur in the bent region of the substrate S due to collision.

The electrostatic chuck 200 may further include a plasma electrode 230. For example, from the perspective of the plane of the electrostatic chuck 200, the plasma electrode 230 may be disposed in a spiral pattern, but the disclosure is not limited thereto. For example, the plasma electrode 230 may be disposed in a lower portion of the heater 210 and the chucking electrode 220, but the disclosure is not limited thereto. The plasma electrode 230 may be connected to the power supply 600 to receive voltage. The plasma electrode 230 may excite the gas of the inner space IS into a plasma state.

The electrostatic chuck 200 may include the drive shaft 240. The drive shaft 240 of the electrostatic chuck 200 may be configured to rotate the electrostatic chuck 200 and/or move the electrostatic chuck 200 up and down. To this end, the drive shaft 240 may include a separate driving unit. However, the disclosure is not limited to the above, and a separate driving device may be connected to the drive shaft 240. For example, a portion of the drive shaft 240 may be disposed in the inner space IS of the chamber 100, and a portion of the drive shaft 240 may extend to the outside of the chamber 100. However, the disclosure is not limited to the above, and the entire drive shaft 240 may be disposed in the inner space IS of the chamber 100.

The substrate processing apparatus 10 may include the shower head 300. The shower head 300 may be disposed in an upper portion of the inner space IS relative to the electrostatic chuck 200 and may include the gas flow path 310 for supplying gas to the substrate S. The gas injectors 320 connected to the gas flow path 310 may be formed on a lower surface 300a of the shower head 300. The shower head 300 may be positioned above the electrostatic chuck 200.

The shower head 300 may be moved in the thickness direction of the substrate S through a driving unit (e.g., a linear motor). For example, the driving unit may be one of the components of the shower head 300, but the disclosure is not limited thereto, and the driving unit may be implemented as a separate driving device connected to the shower head 300. For example, the shower head 300 may be moved in a direction closer to the substrate S by the driving unit.

The processing gas may be injected onto the substrate S by the shower head 300, and accordingly, a process of depositing a film on the substrate S may be performed.

After the process of processing the substrate S with the processing gas supplied through the shower head 300 is completed, the shower head 300 may be moved in a direction away from the substrate S. According to one or more embodiments, with the shower head 300 being fixed in position, processing of the substrate S, such as depositing a film on the substrate S, etc., may be performed.

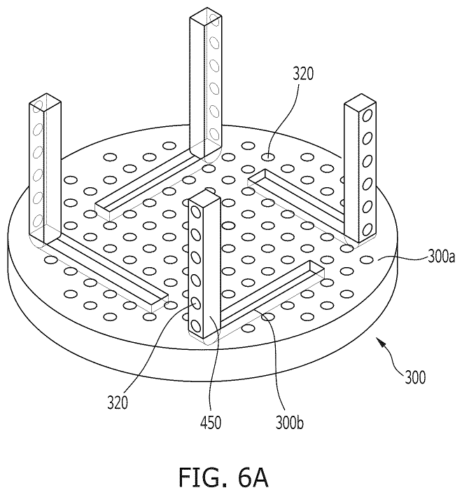

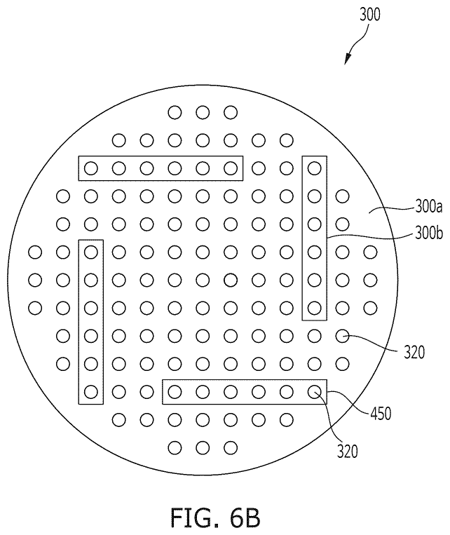

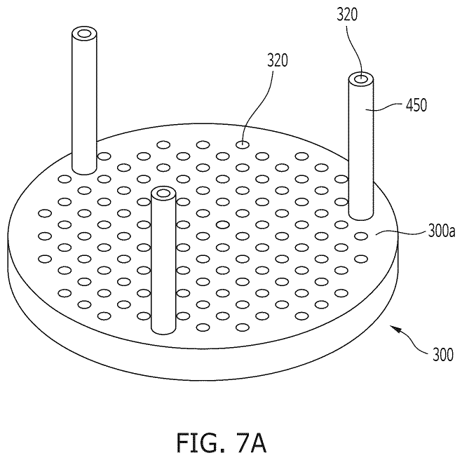

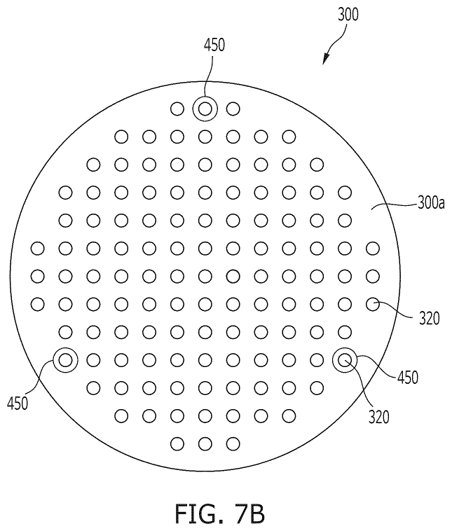

The shower head 300 may include the plurality of gas injectors 320 disposed on the lower surface 300a. The plurality of gas injectors 320 may be disposed at intervals on the lower surface 300a of the shower head 300 (see FIGS. 6A to 7B). The processing gas injected by the shower head 300 may be injected through the gas injectors 320. The gas may be injected relatively uniformly onto the substrate S by the gas injectors 320 disposed at intervals on the lower surface 300a of the shower head 300.

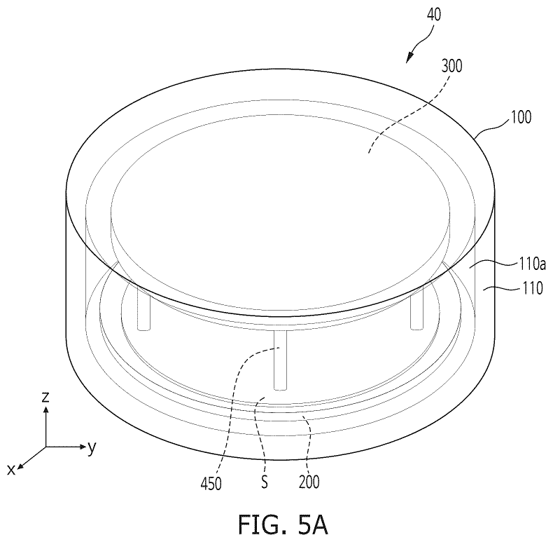

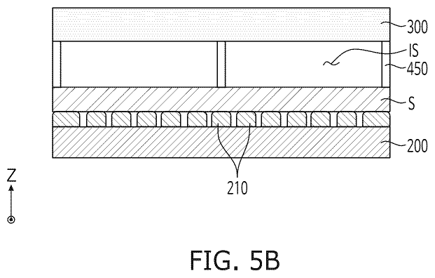

The substrate processing apparatus 10 may include the planarization member 400 for applying force to the substrate S in a direction toward the electrostatic chuck 200 so that at least one region of the substrate S is closer to the electrostatic chuck 200. The planarization member 400 may be disposed on any one of inner side surfaces of the chamber 100. According to another aspect, the planarization member 400 may be disposed on either a lower surface or the side surfaces of the shower head 300 (see FIGS. 5A to 7B).

Referring to FIGS. 2A to 2C, the planarization member 400 may be disposed on the sidewall 110 of the chamber 100. The planarization member 400 may be disposed to protrude from the sidewall 110 of the chamber 100 toward the inner space IS. For example, the planarization member 400 may be disposed on the inner surface 110a of the sidewall 110 of the chamber 100. In addition, the planarization member 400 may have a shape such that it protrudes from the inner surface 110a of the sidewall 110 and is bent, and may be configured to contact the substrate S.

For example, at least one region (hereinafter, a “contact region”) where the planarization member 400 disposed on the sidewall 110 of the chamber 100 contacts the substrate S may be included in a region (hereinafter, an “edge region”) between the edge of the substrate S and a circumferential arc that is at a predetermined interval inward from the edge toward the center of the substrate S. For example, fewer or no semiconductor chips or devices may be disposed in the edge region of the substrate S compared to the other region on the substrate S excluding the edge region. For example, a width of the edge region may be about 0.15 mm, but the disclosure is not limited thereto and the width of the edge region may be about 0.05 mm to 0.2 mm. Further, for example, the interval between the contact region of the planarization member 400 and the edge of the substrate S, when the planarization member 400 is in contact with the substrate S, may be about 0.1 mm. In this case, this interval may be measured in a direction perpendicular to the thickness direction of the substrate S. For example, a straight-line distance between the contact region of the planarization member 400 and the edge of the substrate S on the X-Y plane illustrated in the drawing (e.g., FIG. 2B) may be measured as the interval. However, the interval between the contact region of the planarization member 400 and the edge of the substrate S is not limited to the values or ranges mentioned above, and the interval may be variously changed within a range in which little or no effect is applied on the semiconductor chip or device present on the substrate S when the planarization member 400 contacts the substrate S.

The planarization member 400 may include a first body 401 protruding from the sidewall 110 of the chamber 100 and a second body 402 connected to an end of the first body 401 and bent in a direction perpendicular to a longitudinal direction of the first body 401. The first body 401 may be a portion of the planarization member 400 directly connected to the chamber 100. The first body 401 may protrude in a direction intersecting with the inner surface of the chamber 100. Referring to FIGS. 2A to 2D, the first body 401 may protrude into the interior of the chamber 100 in a direction perpendicular to the inner surface of the chamber 100.

The second body 402 may be a portion of the planarization member 400 which is spaced apart from the inner surface of the chamber 100. The second body 402 may be a portion of the planarization member 400 which is in direct contact with the substrate S when the planarization member 400 applies a force onto the substrate S. The second body 402 may be a portion that is bent from the first body 401. The second body 402 may extend horizontally to the thickness direction of the substrate S. Accordingly, when the second body 402 contacts the substrate S and applies force thereto, the direction of the force may be substantially parallel to the thickness direction of the substrate S. The second body 402 may be a pin portion extending in the thickness direction of the substrate S. The pin portion of the planarization member 400 may contact the substrate S to planarize a bent region of the substrate S.

The planarization member 400 may be configured to be able to move parallel to the thickness direction of the substrate S along the sidewall 110 of the chamber 100.

The chamber 100 with the planarization member 400 disposed therein may be in a fixed state, and the planarization member 400 may be moved along the sidewall 110, and with respect to the substrate S along a direction parallel to the thickness direction of the substrate S. Referring to FIG. 2D, the planarization member 400 may include a driving unit 400m. For example, the driving unit 400m may be disposed within the sidewall 110 of the chamber 100, but this is merely one example, and the driving unit 400m may be disposed outside the chamber 100 or in another portion of the chamber 100. However, the disclosure is not limited to the above, and the planarization member 400 may be configured to be moved along the thickness direction of the substrate S through a separate device connected to the planarization member 400. That is, the planarization member 400 may be configured to be moved in a vertical direction of the substrate processing apparatus 10.

The driving unit 400m may receive a control signal from an external device such as a control unit and be controlled to drive the planarization member 400. For example, the driving unit 400m may be a rack and pinion device connected to the motor, but the disclosure is not limited thereto, and any suitable structure or device may be selected as need arises.

For example, if a region of the substrate S is bent due to thermal expansion, the planarization member 400 may be moved closer to the substrate S by the driving unit 400m and apply force to the substrate S. In order to reduce impact between the electrostatic chuck 200 and the substrate S moved or bent by the applied force, the movement distance of the planarization member 400, driven by the driving unit 400m, may be selected appropriately. For example, the driving unit 400m may control so that the planarization member 400 may stop when the interval between the substrate S and the electrostatic chuck 200 approaches nearly 0 mm. For example, it may be assumed that before the driving unit 400m is driven, the interval between the planarization member 400 and the substrate S is d1 and a thickness of the substrate S is w1. In this case, a movement distance d2 of the planarization member 400, driven by the driving unit 400m, may be a value obtained by subtracting w 1 from d 1. Alternatively, a movement distance of the planarization member 400, driven by the driving unit 400m , may be a value smaller than d2.

According to one or more embodiments, the planarization member 400 may be fixed to the inner surface of the chamber 100 so as be fixed in a position (e.g., in a position in a Z direction) in the thickness direction of the substrate S within the chamber 100. In this case, if the chamber 100 is configured to be moved along the thickness direction of the substrate S, the planarization member 400 may also be moved along the thickness direction of the substrate S as the chamber 100 is moved. The chamber 100 may include a driving unit (e.g., a linear motor) that moves the chamber 100 along the thickness direction of the substrate S. For example, the driving unit may be disposed outside the chamber 100. The driving unit may receive a control signal from an external device such as a control unit and drive the chamber 100.

The planarization member 400 may include a plurality of planarization members 400. The plurality of planarization members 400 may be disposed at equal intervals at the same height along the sidewall 110 of the chamber 100. The plurality of planarization members 400 may be disposed at equal intervals along a circumference of an imaginary circle centered around the center of the substrate S, while being in contact with the substrate S. For example, if the chamber 100 has a cylindrical shape, the planarization member 400 may be disposed on the sidewall 110 along an azimuthal direction based on a central axis of the chamber 100. If there are two planarization members 400, the planarization members 400 may be disposed on the sidewall 110 at positions facing each other, and an azimuth angle between the two planarization members 400 may be substantially 180 degrees. According to other aspects, if there are three planarization members 400, the planarization members 400 may be disposed on the sidewall 110 and spaced apart from each other by an azimuth angle of 120 degrees. If the number of planarization members 400 is n (where, n is a natural number greater than or equal to 2), the planarization members 400 may be disposed on the sidewall 110 and spaced apart from each other by an azimuth angle of 360/n degrees.

The gas supply 500 may store processing gas for use in the substrate processing or may supply the processing gas to the inner space IS of the chamber 100. The gas supply 500 may include a gas supply pipe 510 that communicates with the interior of the chamber 100. The gas supply pipe 510 may be connected to the gas flow path of the shower head 300 so as to supply the processing gas into the inner space of the chamber 100 through the shower head 300.

The power supply 600 may supply power necessary for generating plasma to the inner space IS. The power supply 600 may be connected to the plasma electrode 230 and supply power to the plasma electrode 230 to excite the processing gas of the inner space IS into a plasma state. For example, the power supply 600 may apply radio frequency (RF) power in the form of electromagnetic waves with a predetermined frequency and intensity.

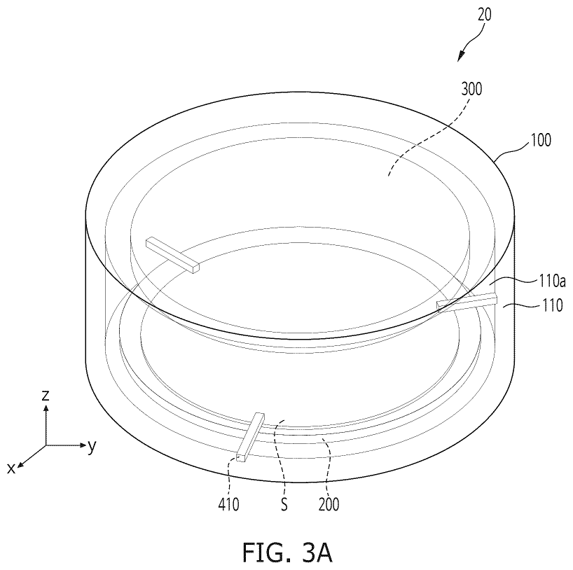

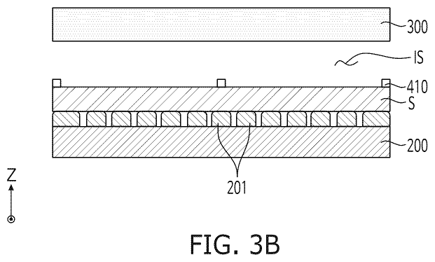

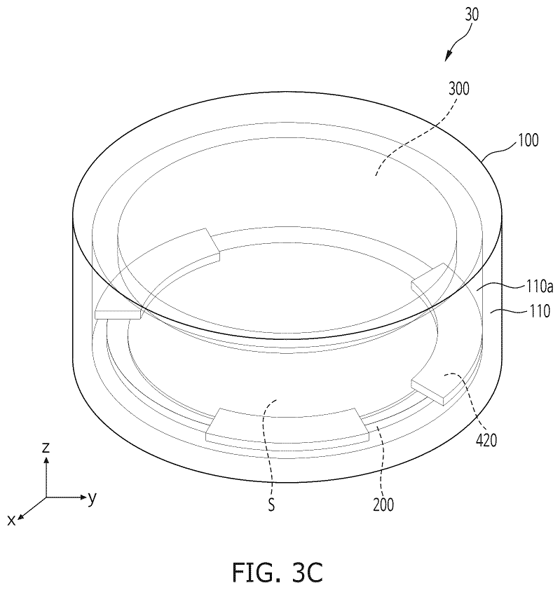

FIG. 3A is a schematic diagram illustrating a part of a substrate processing apparatus according to one or more embodiments; FIG. 3B is a schematic cross-sectional view illustrating a portion of the substrate processing apparatus according to one or more embodiments. FIG. 3C is a schematic diagram illustrating a portion of the substrate processing apparatus according to one or more embodiments. Referring to FIGS. 3A and 3B, a substrate processing apparatus 20 may include a planarization member 410. The planarization member 410 may have a rod-like shape protruding in a direction perpendicular to the thickness direction of the substrate S. A longitudinal direction of the planarization member 410 may be substantially perpendicular to the thickness direction of the substrate S. As the planarization member 410 is moved in the thickness direction of the substrate S and approaches the substrate S, a lower surface of the planarization member 410 may be brought into contact with the substrate S, thereby planarizing the bent region of the substrate S.

The planarization member 410 may be disposed to protrude from the sidewall 110 of the chamber 100 to the inner space IS. For example, a region in which an end of the planarization member 410 protruding from the chamber 100 is in contact with the substrate S may be included in the edge region of the substrate S. The ranges and shapes of the edge region are the same as those described above with reference to FIGS. 2A to 2D, and thus, will not be redundantly described below.

Referring to FIG. 3C, a substrate processing apparatus 30 may include a planarization member 420. The planarization member 420 may extend in an azimuthal direction based on the center of the chamber 100 along the inner surface 110a of the sidewall 110 of the chamber 100. If the chamber 100 has a cylindrical shape, the azimuthal direction may indicate a tangential direction of an inner circumference of the inner surface 110a of the sidewall 110 of the chamber 100. For example, at least one of a plurality of planarization members 420 may extend to have an azimuth angle of about 60 degrees. For example, as illustrated in FIG. 3C, the planarization member 420 may include three planarization members 420, and each of the planarization member may extend over an azimuth of 60 degrees.

As illustrated in FIG. 3C, the planarization member 420 may be configured to extend along the azimuthal direction such that the planarization member 420 may apply pressure over a wider area on the substrate S. Accordingly, through the planarization member 420, it is possible to apply force more uniformly and over a relatively wide area in the edge region of the substrate S and planarize the substrate S more effectively.

However, the disclosure is not limited to the above, and the planarization member 420 may be disposed to extend over the entire azimuth of the sidewall 110 of the chamber 100, or may be disposed to have various shapes as need arises.

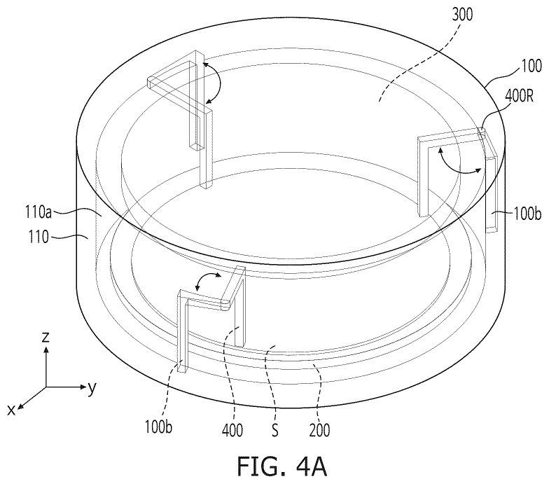

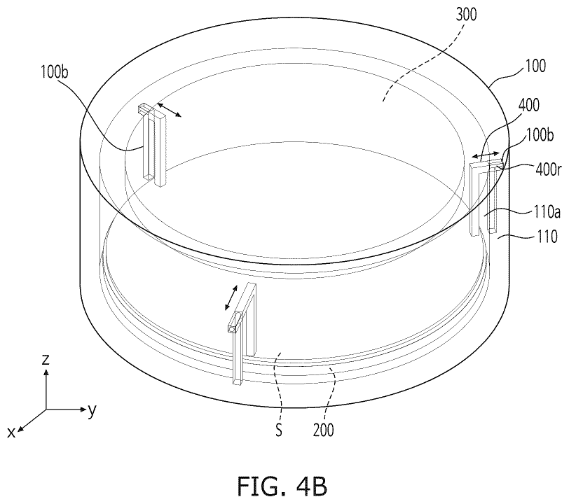

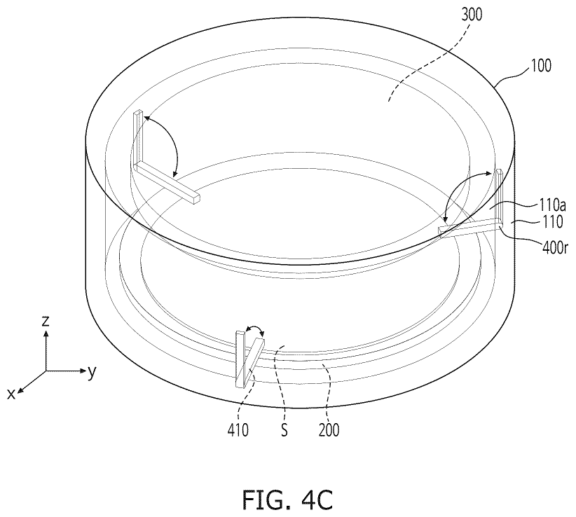

FIG. 4A is a diagram illustrating a portion of the chamber in which the planarization member and a receiving groove of the substrate processing apparatus are disposed according to one or more embodiments. FIG. 4B is a diagram illustrating a portion of the chamber in which the planarization member and the receiving groove of the substrate processing apparatus are disposed according to one or more embodiments. FIG. 4C is a diagram illustrating a structure of the planarization member and the receiving groove of the substrate processing apparatus according to one or more embodiments. Referring to FIGS. 4A and 4C, the sidewall 110 of the chamber 100 may include a receiving groove 100b that may receive at least a portion of the planarization member 400. Further, at least a portion of the planarization member 400 may be configured such that it may be received in the receiving groove 100b or protrude from the receiving groove 100b. Since the chamber 100 includes the receiving groove 100b to receive at least a portion of the planarization member 400, it is possible to minimize or prevent interferences that may occur in other processes due to the presence of the planarization member 400 disposed within the chamber 100, before the substrate processing of the planarization member 400 or after the substrate processing is completed.

The receiving groove 100b of the chamber 100 may have the same shape as a cross-sectional shape of the planarization member 400 viewed from one direction. Accordingly, the planarization member 400, which protrudes inward and is disposed within the interior of the chamber 100, may be moved into the receiving groove 100b and received therein. For example, the entire planarization member 400 may be inserted into the receiving groove 100b. Alternatively, if the depth of the receiving groove 100b is relatively shallow, a portion of the planarization member 400 may be inserted into the receiving groove 100b. Since the planarization member 400 received in the receiving groove 100b does not protrude or only partially protrudes into the interior of the chamber 100, the planarization member 400 may have little or no effect on the subsequent process.

As shown in FIG. 4A, at least some of the planarization members 400 may be rotated on a rotational axis parallel to the inner surface 110a of the sidewall 110 of the chamber 100 in which the planarization members 400 are disposed, and may be received in or protrude from the receiving grooves 100b. For example, the rotational axis may be parallel to a height direction of the sidewall. In order to control so that the planarization member 400 is inserted into or protrudes from the receiving groove 100b, the planarization member 400 or the chamber 100 may include a position adjustment unit 400r. For example, the position adjustment unit 400r may include a hinge member, and the planarization member 400 may be rotated on the rotational axis of the hinge member to be inserted into or protrude from the receiving groove 100b. Alternatively, this position adjustment of the planarization member 400 being inserted into or protruding from the receiving groove 100b may be controlled by the driving unit 400m included in the planarization member 400 or the chamber 100. The driving unit 400m may be configured to rotate the planarization member 400.

As illustrated in FIG. 4B, at least some of the planarization members 400 may be translated in a direction perpendicular to the inner surface 110a of the sidewall 110 of the chamber 100 in contact with the planarization members 400 to be received in or protrude from the receiving groove 100b. In order to control so that the planarization member 400 is inserted into or protrudes from the receiving groove 100b, the planarization member 400 or the chamber 100 may include the position adjustment unit 400r. For example, the position adjustment unit 400r may be a rack and pinion device connected to a motor, but the disclosure is not limited thereto and various types of devices may be used for driving. Alternatively, driving the planarization member 400 to be inserted into or protrude from the receiving groove 100b may be controlled by the planarization member 400 or the driving unit 400m included in the chamber 100. The driving unit 400m may be configured to translate the planarization member 400.

As shown in FIG. 4C, at least some of the planarization members 410 may be rotated on a rotational axis parallel to the inner surface 110a of the sidewall 110 of the chamber 100 in which the planarization members 410 are disposed, and may be received in or protrude from the receiving grooves 100b. For example, the rotational axis may be parallel to an azimuthal direction of a point located on the inner surface of the sidewall. In order to control so that the planarization member 410 is inserted into or protrudes from the receiving groove 100b, the planarization member 410 or the chamber 100 may include the position adjustment unit 400r.

For example, the planarization members 400, 410, 420 described above with reference to FIGS. 3A to 4C may be used to planarize the shape of the plane of the substrate S that is bent due to thermal expansion. If the planarization of the substrate S by the planarization member 400 is completed, chucking for fixedly securing the substrate may be performed. Further, for the subsequent processes (e.g., deposition on substrate, etc.) with respect to the substrate S fixed to the electrostatic chuck 200, the planarization member 400 may be spaced apart from the substrate S and inserted and received into the receiving groove 100b of the chamber 100. Accordingly, defects such as scratches or cracks caused due to collisions with the electrostatic chuck 200 on the back surface of the bent substrate during the chucking process may be reduced. Further, it is possible to minimize or prevent possible in-process interferences that may occur due to the presence of the planarization members 400, 410, 420 before and after the process of using the planarization members 400, 410, 420.

FIG. 5A is a schematic diagram illustrating a portion of the substrate processing apparatus according to one or more embodiments. FIG. 5B is a schematic cross-sectional view illustrating a portion of the substrate processing apparatus according to one or more embodiments. FIG. 6A is a perspective view illustrating a lower surface of the shower head of the substrate processing apparatus according to one or more embodiments. FIG. 6B is a plan view of the shower head of the substrate processing apparatus of FIG. 6A. FIG. 7A is a perspective view illustrating the lower surface of the shower head of the substrate processing apparatus according to one or more embodiments. FIG. 7B is a plan view of the shower head of the substrate processing apparatus of FIG. 7A.

Referring to FIGS. 5A and 5B, a substrate processing apparatus 40 may include the chamber 100 having the inner space IS for processing the substrate S, the electrostatic chuck 200 disposed in the lower portion of the inner space IS, configured to support the substrate S, and applying the electric force to the substrate S, the shower head 300 including the gas flow path 310 disposed in the upper portion of the inner space IS and supplying gas to the substrate S, and a planarization member 450 applying force to at least one region of the substrate S in a direction toward the electrostatic chuck 200, in which the electrostatic chuck 200 may include the heater 210 that may heat the substrate.

The planarization member 450 may be disposed on the lower surface 300a of the shower head 300. The substrate processing apparatus 40 may apply force to at least one region of the substrate S through the planarization member 450, and if the substrate S includes a portion bent by heat, for example, the planarization member 450 may apply the force on the bent portion to planarize the substrate S. Accordingly, defects that may occur due to bending of the substrate S may be reduced in the subsequent processes applied to the substrate S. For example, occurrence of falling particles or plate particles formed due to collision between a portion of the substrate S and the electrostatic chuck may be prevented.

Descriptions of the chamber 100, the electrostatic chuck 200, and the shower head 300 included in the substrate processing apparatus 40 overlap those described above, and redundant description will be omitted. Further, the substrate processing apparatus 40 may include a gas supply and/or a power supply, but as these overlap with the above description, redundant description thereof will be omitted.

According to one or more embodiments, the substrate processing apparatus 40 may include the planarization member 450, and the planarization member 450 may be disposed on the lower surface 300a of the shower head 300. For example, the planarization member 450 may be disposed to protrude from the lower surface 300a of the shower head 300.

At least one region (hereinafter, a “contact region”) in which the planarization member 450 protruding from the shower head 300 contacts the substrate S may be disposed in a region (i.e., an “edge region”) between the edge of the substrate S and a circumference that is at a predetermined interval inward from the edge toward the center of the substrate S. For example, fewer or no semiconductor chips or devices may be disposed in the edge region of the substrate S compared to the other region on the substrate S excluding the edge region. For example, the predetermined interval may be about 0.15 mm, but is not limited thereto, and it may be 0.05 mm to 0.2 mm. For example, the interval between the substrate contact region of the planarization member 400 and the edge of the substrate S may be about 0.1 mm. In this case, this interval may be measured in a direction perpendicular to the thickness direction of the substrate S. For example, a straight-line distance between the substrate contact region of the planarization member 400 and the edge of the substrate S on an XY plane may be measured as the interval. However, the substrate contact region of the planarization member 400 is not limited to the values or ranges mentioned above, and may be varied within a range that has little or no effect on the semiconductor chips or devices present on the substrate S when the planarization member 400 contacts the substrate S. The planarization member 450 may be configured to move in parallel to the thickness direction of the substrate S.

The shower head 300 with the planarization member 450 disposed therein may be maintained in the fixed state, and the planarization member 450 may be moved with respect to the shower head 300 in a direction relatively parallel to the thickness direction of the substrate S. In this case, the shower head 300 may include a receiving groove that may receive a portion of the planarization member 450 or a through hole through which the planarization member 450 may penetrate the shower head 300. The planarization member 450 may include a driving unit (e.g., a linear motor). For example, the driving unit may be disposed inside the shower head 300, but this is only an example and the driving unit may be disposed outside the shower head 300. However, the disclosure is not limited to the above, and the planarization member 450 may be moved along the thickness direction of the substrate S through a separate driving device connected to the planarization member 450. That is, the planarization member 450 may be configured to be moved in a vertical direction of the substrate processing apparatus 40.

The driving unit may receive a control signal from an external device such as a control unit and drive the planarization member 450. The driving unit may be a rack and pinion device connected to the motor, but the disclosure is not limited thereto, and a suitable driving device may be selected as need arises.

For example, if a region of the substrate S is bent due to thermal expansion, the planarization member 450 may be moved closer to the substrate S through the driving unit to apply force to the substrate S. In this case, in order to reduce the impact between the substrate S and the electrostatic chuck 200, a moving distance of the planarization member 450 may be suitably selected. For example, the planarization member 450 may be controlled to stop when the interval between the substrate S and the electrostatic chuck 200 approaches nearly 0 mm. For example, it is assumed that the interval between the substrate S and the initial position of the planarization member 450 is d3, and a thickness of the substrate S is w1. In this case, a movement distance d4 of the planarization member 450 may be a value obtained by subtracting w1 from d3. Alternatively, the movement distance of the planarization member 450 may be a value smaller than d4.

According to another aspect, the planarization member 450 may be fixed to the shower head 300 that includes the planarization member 450 disposed therein. In this case, the position of the planarization member 450 in the thickness direction of the substrate S (e.g., the position in the Z direction) is fixed, and as the shower head 300 is moved along the thickness direction of the substrate S, the planarization member 450 may also be moved along the thickness direction of the substrate S. To this end, the shower head 300 may include a driving unit (e.g., a linear motor). For example, the driving unit may be disposed outside the shower head 300. The driving unit may receive a control signal from an external device such as a control unit and drive the shower head 300.

The planarization member 450 may include a plurality of planarization members 450. The planarization members 450 may be disposed at equal intervals along a circumference of an imaginary circle centered around the center of the substrate S, while being in contact with the substrate S. Alternatively, the planarization member 450 may include a plurality of planarization members 450 disposed at equal intervals along the circumferences of a plurality of concentric circles on the lower surface 300a of the shower head 300. For example, the plurality of planarization members 450 may be disposed at equal intervals along a circumference of an imaginary circle centered around the center of the lower surface 300a of the shower head 300. For example, if the lower surface 300a of the shower head 300 has a circular shape, the planarization members 450 may be disposed in an azimuthal direction of a circumference of the imaginary circle centered around the center of the lower surface 300a. According to an example, if there are two planarization members 450, the planarization members 450 may be disposed to face each other at two points which are both ends of the diameter of the circle, in which the azimuth between the two planarization members 450 may be substantially 180 degrees. According to another aspect, if there are three planarization members 450, the planarization members 450 may be disposed to be spaced apart from each other by an azimuth angle of 120 degrees on the circumference of the circle. If the number of planarization members 450 is n (where, n is a natural number of 2 or more), the planarization members 450 may be disposed to be spaced apart from each other by an azimuth angle of 360/n degrees on the circumference of the circle.

The planarization member 450 may extend along an azimuthal direction on a circumference of an imaginary circle centered around the center of the lower surface 300a of the shower head 300. The planarization member 450 may extend along the circumferences of a plurality of concentric circles on the lower surface 300a of the shower head 300. For example, one of the plurality of planarization members 450 may be disposed to extend over a predetermined azimuth size.

Since the planarization member 450 is disposed to extend along the azimuthal direction, it is possible to apply force over a wider area on the substrate S. Accordingly, through the planarization member 450, it is possible to apply force to the edge region of the substrate S more uniformly and planarize the substrate S more efficiently and flatly compared to situations where this is not the case.

Referring to FIGS. 6A to 7B, the shower head 300 may include a receiving groove 300b that may receive at least a portion of the planarization member 450. Further, at least a portion of the planarization member 450 may be configured such that it may be received in the receiving groove 300b or protrude from the receiving groove 300b. Since the shower head 300 includes the receiving groove 300b to receive at least a portion of the planarization member 450, it is possible to minimize or prevent interference that may occur in other processes due to the presence of the planarization member 450, before the substrate processing of the planarization member 450 or after the substrate processing is completed. For example, an entrance of the receiving groove 300b included in the shower head 300 may be disposed on the lower surface 300a of the shower head 300.

The receiving groove 300b of the shower head 300 may have the same shape as a cross-sectional shape of the planarization member 450 viewed from one direction. Accordingly, the planarization member 450 disposed in the one direction may be received in the receiving groove 300b. For example, the entire planarization member 450 may be inserted into the receiving groove 300b. Alternatively, if the depth of the receiving groove 300b is relatively shallow, a portion of the planarization member 450 may be inserted into the receiving groove 300b. The planarization member 450 received in the receiving groove 300b may have less impact on the process where the planarization member 450 is not used or may not affect the process at all, compared to when the planarization member 450 protrudes out of the receiving groove 300b.

The receiving groove 300b included in the substrate processing apparatus 40 may be the receiving groove 300b including an opening formed in the lower surface 300a of the shower head 300. However, the disclosure is not limited to the above, and the substrate processing apparatus 40 may include a through hole penetrating the lower surface 300a of the shower head 300. In this case, a portion of the planarization member 450 may be received in the through hole.

As shown in FIG. 6A, at least a portion of the planarization member 450 may be rotated on a rotational axis parallel to the lower surface 300a of the shower head 300 in which the planarization member 450 is disposed, and may be received in or protrude from the receiving groove 300b. The planarization member 450 or the shower head 300 may include a position adjustment unit to allow the planarization member 450 to be inserted into or protrude from the receiving groove 300b. For example, the position adjustment unit may include a hinge member, and the planarization member 450 may be rotated on the rotational axis of the hinge member to be inserted into or protrude from the receiving groove 300b. Alternatively, this position adjustment of the planarization member 450 being inserted into or protruding from the receiving groove 300b may be controlled by the driving unit included in the planarization member 450 or the shower head 300.

As shown in FIG. 6B, the planarization member 450 disposed in the shower head 300 may include the gas injectors 320. For example, if the planarization member 450 is received in the receiving groove 300b of the lower surface 300a of the shower head 300, at least one of the plurality of gas injectors 320 may be disposed on one side of the planarization member 450 exposed on the lower surface 300a. The planarization member 450 of FIG. 6B may include the plurality of gas injectors 320 disposed on the side surface of the planarization member 450. Therefore, after the planarization process of the substrate shape using the planarization member 450, the planarization member 450 may be received in the receiving groove 300b of the shower head 300, and at this time, gas may be injected onto the substrate S through the gas injector 320 included in the planarization member 450. Accordingly, due to the planarization member 450 being disposed on the lower surface 300a of the shower head 300, the gas injection unit is not disposed at the position where the planarization member 450 is disposed, and as a result, the problem of possible irregular gas injection may be reduced. However, the disclosure is not limited to the above, and the planarization member 450 may not include a gas injector 320, and in this case, the planarization member 450 may be received in the receiving groove 300b formed between the plurality of gas injectors 320.

As shown in FIG. 7A, at least a portion of the planarization member 450 may be moved in a direction perpendicular to the lower surface 300a of the shower head 300 which is in contact with the planarization member 450 to be received in or protrude from the receiving groove 300b. The planarization member 450 or the shower head 300 may include a position adjustment unit (e.g., a linear motor) to allow the planarization member 450 to be inserted into, or to protrude from, the receiving groove 300b. For example, the position adjustment unit may be a rack and pinion device connected to the motor, but the disclosure is not limited thereto. Alternatively, the operation of inserting or protruding of the planarization member 450 into or from the receiving groove 300b may be controlled by the driving unit included in the planarization member 450 or the shower head 300.

As shown in FIG. 7B, the planarization member 450 disposed in the shower head 300 may include the gas injectors 320. For example, if the planarization member 450 is received in the receiving groove 300b of the lower surface 300a of the shower head 300, at least one of the plurality of gas injectors 320 may be disposed on one side of the planarization member 450 exposed on the lower surface 300a. Therefore, after the planarization process with the planarization member 450, the planarization member 450 may be received in the receiving groove 300b of the shower head 300, and at this time, gas may also be injected onto the substrate S through the gas injector 320 included in the planarization member 450.

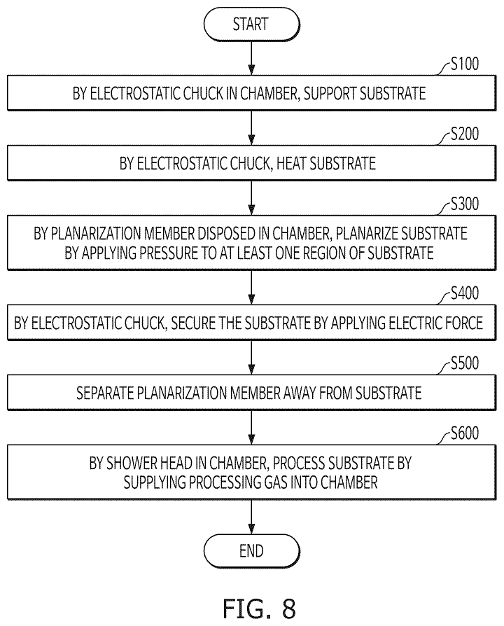

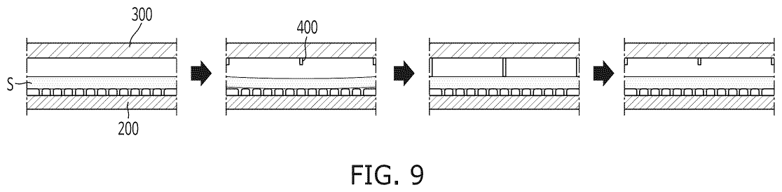

FIG. 8 is a flowchart provided to explain a method for processing a substrate. FIG. 9 is a schematic diagram illustrating a sequence of a method for processing a substrate.

Referring to FIG. 8, the method for processing the substrate may include supporting the substrate with the electrostatic chuck in the chamber of the substrate processing apparatus at S100, heating the substrate with the electrostatic chuck at S200, planarizing the substrate by applying pressure to at least one region of the substrate by the planarization member disposed inside the chamber at S300, securing the substrate with the electrostatic chuck by applying the electric force at S400, separating the planarization member away from the substrate at S500, and supplying the processing gas into the chamber with the shower head in the chamber to process the substrate at S600. The planarization member may be disposed on at least one of the inner surface of the sidewall of the chamber or the lower surface of the shower head.

The substrate processing apparatus for use with the method for processing the substrate according to one or more embodiments may be the substrate processing apparatuses 10, 20, 30, and 40 described above with reference to FIGS. 2A to 7B.

Referring to FIG. 9, at operation S100 of supporting the substrate with the electrostatic chuck in the chamber, the substrate S may be loaded into the inner space in the chamber. The loaded substrate S may be supported by the electrostatic chuck 200 in the chamber. For example, the substrate S may be disposed on the electrostatic chuck 200 with the center of the substrate S being aligned with the electrostatic chuck 200.

At operation S200 of heating the substrate with the electrostatic chuck, the substrate S may be heated by the heater included in the electrostatic chuck 200. For example, heating in the heating operation S200 may include heating the inner space of the chamber to about 550 degrees Celsius to about 700 degrees Celsius. Deformation may occur in at least a partial region (e.g., edge region) of the substrate S by bending, causing the corresponding region of the substrate S to be spaced apart from the electrostatic chuck 200.

At operation S300 of planarizing, the planarization member 400 may be moved close to the substrate S. For example, the planarization member 400 may be moved within the substrate processing apparatus parallel to the thickness direction of the substrate S. The planarization member 400 may be moved close to the substrate S and contact at least one region of the substrate S that is bent. The at least one bent region of the substrate S may be subjected to pressure by the planarization member 400 toward the electrostatic chuck 200. The at least one bent region of the substrate S may be moved closer to the electrostatic chuck 200 and as a result, the substrate S may be flattened overall.

The operation S300 of planarizing may be performed simultaneously with the operation S200 of heating. Alternatively, the operation S300 of planarizing may be performed during the operation S200 of heating. The operation S300 of planarizing may be performed together after several seconds to several minutes (e.g., 1 or 2 minutes) from the operation S200 of heating.

While the planarization member 400 is planarizing the substrate S during the operation S300 of planarizing, the movement distance of the planarization member 400 may be adjusted so as to prevent the substrate S from colliding with the electrostatic chuck 200 or to minimize the impact even if the substrate S collides with the electrostatic chuck 200. For example, the movement distance of the planarization member 400 may be selected within the range of a difference between the distance between the initial position of the planarization member 400 and the substrate spaced apart from the same, and the thickness of the substrate S.

At operation S400 of securing the substrate by applying the electric force with the electrostatic chuck, the substrate S may be subjected to the electric force applied by the electrostatic chuck 200 and adhered to the electrostatic chuck 200. For example, the substrate S may be adhered onto the protrusions included in the electrostatic chuck 200. The substrate S may be fixed on the electrostatic chuck 200 by the electric force. While the substrate S is fixed on the electrostatic chuck 200, subsequent processes may follow.

The operation S400 of securing may be performed in the middle of the operation S300 of planarizing. For example, if at least one bent region of the substrate is moved toward the electrostatic chuck 200 by a predetermined distance at the operation S300 of planarizing, the operation S400 of securing may proceed. According to another example, after the operation S300 of planarizing is performed, the operation S400 of securing may be performed together after several seconds to several minutes.

At operation S500 of separating the planarization member away from the substrate, the planarization member 400 may be spaced apart from the substrate S before the subsequent process is performed on the substrate S. For example, the planarization member 400 may be spaced apart from the substrate S in a direction away from the substrate S. Alternatively, the planarization member 400 may be spaced apart from the substrate while being partially received in the receiving groove disposed in the chamber or the shower head. Accordingly, possible interferences in the subsequent process due to the presence of the planarization member may be reduced.

At operation S600 of processing the substrate by supplying the processing gas into the chamber with the shower head in the chamber, the processing gas supplied into the chamber may be excited into a plasma state by the voltage applied by the power supply. Accordingly, a process of depositing a film on the substrate may be performed.

Although the present disclosure has been described above by way of certain aspects and drawings, the present disclosure is not limited thereto, and it goes without saying that various changes and modifications can be made within the equivalent scope of the technical idea of the present disclosure and the claims to be described below by those of ordinary skill in the art.

What is claimed is:

1. An apparatus for processing a substrate, the apparatus comprising:
a chamber comprising an inner space;
an electrostatic chuck in a lower portion of the inner space, wherein the electrostatic chuck is configured to support and adhere to the substrate;
a shower head in an upper portion of the inner space, the shower head comprising a gas flow path configured to supply a processing gas into the inner space; and
a planarization member configured to apply pressure to at least one region of the substrate in a direction toward the electrostatic chuck,
wherein the electrostatic chuck comprises a heater capable of heating the substrate.

2. The apparatus of claim 1, wherein the planarization member is on an inner surface of a sidewall of the chamber.

3. The apparatus of claim 2,
wherein the sidewall of the chamber comprises a receiving groove configured to receive at least a portion of the planarization member, and
wherein the at least the portion of the planarization member is configured to be received in or to protrude from the receiving groove.

4. The apparatus of claim 3, wherein the at least the portion of the planarization member is rotatable along a rotational axis parallel to the inner surface of the sidewall of the chamber.

5. The apparatus of claim 3, wherein the at least the portion of the planarization member is translatable in a direction perpendicular to the inner surface of the sidewall of the chamber.

6. The apparatus of claim 1, wherein the planarization member is on a lower surface of the shower head.

7. The apparatus of claim 6,
wherein the shower head comprises a receiving groove configured to receive at least a portion of the planarization member, and
wherein the at least the portion of the planarization member is configured to be received in or to protrude from the receiving groove.

8. The apparatus of claim 7, wherein the at least the portion of the planarization member is rotatable along a rotational axis parallel to the lower surface of the shower head.

9. The apparatus of claim 7, wherein the at least the portion of the planarization member is translatable in a direction perpendicular to the lower surface of the shower head.

10. The apparatus of claim 7, wherein the planarization member comprises a gas injector connected to the gas flow path.

11. The apparatus of claim 1, wherein the at least one region of the substrate comprises a region between an edge of the substrate and a circumferential arc spaced 0.15 mm toward a center of the substrate from the edge.

12. The apparatus of claim 1, wherein the planarization member comprises:
a first body protruding from an inner surface of a sidewall of the chamber; and
a second body connected to an end of the first body and bent in a direction perpendicular to a longitudinal direction of the first body.

13. The apparatus of claim 12, wherein the second body extends from the end of the first body in a direction parallel to a thickness direction of the substrate.

14. The apparatus of claim 1, wherein the planarization member comprises a plate comprising a plane perpendicular to a thickness direction of the substrate.

15. The apparatus of claim 1, wherein the planarization member extends in an azimuthal direction along an inner surface of a sidewall of the chamber or along circumferences of a plurality of concentric circles on a lower surface of the shower head.

16. The apparatus of claim 1, wherein the planarization member comprises a plurality of planarization members, wherein the plurality of planarization members are disposed at a same height along an inner surface of a sidewall of the chamber, or are disposed at equal intervals along circumferences of a plurality of concentric circles on a lower surface of the shower head.

17. The apparatus of claim 1,
wherein the planarization member is fixed to a sidewall of the chamber or to a lower surface of the shower head, and
wherein the chamber or the shower head are configured to be movable in parallel to a thickness direction of the substrate.

18. The apparatus of claim 1, wherein the planarization member is configured to be movable along a sidewall of the chamber in parallel to a thickness direction of the substrate.

19. An apparatus for processing a substrate, the apparatus comprising:
a chamber defining an inner space;
an electrostatic chuck in a lower portion of the inner space, wherein the electrostatic chuck is configured to support and adhere to the substrate;
a gas supply configured to supply a processing gas to the inner space;
a shower head in an upper portion of the inner space, the shower head comprising a gas flow path connected to the gas supply;
a power supply configured to supply power to generate a plasma in the inner space; and
a planarization member configured to apply pressure to at least one region of the substrate in a direction toward the electrostatic chuck,
wherein the electrostatic chuck comprises a heater capable of heating the substrate.

20. A method for processing a substrate, the method comprising:
supporting the substrate using an electrostatic chuck in a chamber;
heating the substrate by the electrostatic chuck;
planarizing the substrate by applying pressure to at least one region of the substrate using a planarization member inside the chamber;
securing the substrate by applying an electric force using the electrostatic chuck;
separating the planarization member from the substrate; and
supplying a processing gas into the chamber through a shower head inside the chamber,
wherein the planarization member is on at least one of an inner surface of a sidewall of the chamber or a lower surface of the shower head.
